(19) United States
(12) Patent Application Publication
(10) Pub. No.: US 2024/0210509 A1
(43) Pub. Date: Jun. 27, 2024

(54) SENSOR CIRCUITS, ELECTRONIC DEVICES, AND METHODS FOR PERFORMING INTERNAL CALIBRATION OPERATIONS

(71) Applicant: SK hynix Inc., Icheon-si Gyeonggi-do (KR)

(72) Inventors: Dong Hyun HWANG, Icheon-si Gyeonggi-do (KR); Se Won LEE, Icheon-si Gyeonggi-do (KR)

(73) Assignee: SK hynix Inc., Icheon-si Gyeonggi-do (KR)

(21) Appl. No.: 18/193,462

(22) Filed: Mar. 30, 2023

(30) Foreign Application Priority Data
Dec. 21, 2022 (KR) 10-2022-0181042

(51) Int. Cl. G01R 35/00; G01R 31/28; G01R 31/316

(52) U.S. Cl. CPC G01R 35/005; G01R 31/2829; G01R 31/316

(57) ABSTRACT

A sensor circuit includes a sensing voltage generating circuit configured to generate a sensing voltage set to have a voltage level corresponding to a sensing condition. The sensor circuit also includes a comparison signal generating circuit configured to compare the sensing voltage with at least one reference voltage to generate at least one comparison signal. The sensor circuit further includes a voltage code calibrating circuit configured to calibrate at least one voltage code for adjusting a voltage level of the reference voltage, based on the at least one comparison signal.

### CROSS-REFERENCE TO RELATED APPLICATIONS

The present application claims priority under 35 U.S.C. 119(a) to Korean Patent Application No. 10-2022-0181042, filed on Dec. 21, 2022, in the Korean Intellectual Property Office, which is incorporated herein by reference in its entirety.

### BACKGROUND

### 1. Technical Field

Some embodiments of the present disclosure relate to sensor circuits, electronic devices, and methods for performing internal calibration operations.

### 2. Related Art

Recently, electronic devices are equipped with sensor circuits capable of sensing various operation conditions to adjust the speed and activation of internal operations. The operation conditions sensed by the sensor circuit may include temperature, light intensity, and the like. The electronic devices may perform internal operations controlled in various ways according to temperature and light intensity. For example, the electronic device may increase the speed of an internal operation as the temperature decreases. As another example, the electronic device may activate the internal operation when the light intensity is sensed to be greater than a preset value.

### SUMMARY

In accordance with an embodiment of the present disclosure, a sensor circuit includes: a sensing voltage generating circuit configured to generate a sensing voltage set to have a voltage level corresponding to a sensing condition; a comparison signal generating circuit configured to compare the sensing voltage with at least one reference voltage to generate at least one comparison signal; and a voltage code calibrating circuit configured to calibrate at least one voltage code for adjusting a voltage level of the at least one reference voltage, based on the at least one comparison signal.

In accordance with another embodiment of the present disclosure, an electronic device includes: a sensor circuit configured to compare a sensing voltage set to have a first voltage level under a first sensing condition with at least one reference voltage to generate at least one comparison signal, and configured to calibrate a first voltage code, based on the at least one comparison signal. The electronic device also includes a processor configured to adjust speed and activation of an internal operation, based on the first voltage code.

Also in accordance with the present disclosure is a method of performing an internal calibration operation. The method includes: generating a sensing voltage se-t to have a first voltage level under a first sensing condition; comparing the sensing voltage with at least one reference voltage to generate at least one comparison signal; calibrating a first voltage code, based on the at least one comparison signal; generating a sensing voltage set to have a second voltage level under a second sensing condition; comparing the sensing voltage with the at least one reference voltage to generate at least one comparison signal; and calibrating a second voltage code, based on at least one comparison signal.

### BRIEF DESCRIPTION OF THE DRAWINGS

FIG. 1 is a block diagram illustrating a configuration of a sensor circuit according to an embodiment of the present disclosure.

FIG. 2 is a circuit diagram according to an example of a reference voltage generating circuit included in the sensor circuit illustrated in FIG. 1.

FIG. 3 is a circuit diagram according to an example of a comparison signal generating circuit included in the sensor circuit illustrated in FIG. 1.

FIGS. 4 to 7 are diagrams illustrating internal calibration operations performed for each voltage level of a sensing voltage generated by the sensor circuit illustrated in FIG. 1.

FIGS. 8 and 9 are diagrams illustrating a two-point internal calibration operation performed in the sensor circuit illustrated in FIG. 1.

FIGS. 10 and 11 are diagrams illustrating a method of calculating calibrated voltage codes under sensing conditions extended from voltage codes calibrated in internal calibration operations performed in the sensor circuit illustrated in FIG. 1.

FIG. 12 is a block diagram illustrating a configuration of a sensor circuit according to another embodiment of the present disclosure.

FIG. 13 is a circuit diagram according to an example of a reference voltage generating circuit included in the sensor circuit illustrated in FIG. 12.

FIGS. 14 and 15 are diagrams illustrating a four-point internal calibration operation performed in the sensor circuit illustrated in FIG. 1.

FIG. 16 is a circuit diagram according to another example of the reference voltage generating circuit included in the sensor circuit illustrated in FIG. 12.

FIG. 17 is a block diagram illustrating a configuration of an electronic device according to an embodiment of the present disclosure.

FIG. 18 is a block diagram illustrating a configuration of an electronic device according to another embodiment of the present disclosure.

FIG. 19 is a graph illustrating operations in which analog signals are sequentially calibrated for each voltage level of sensing voltages according to a plurality of internal calibration operations.

### DETAILED DESCRIPTION OF THE EMBODIMENTS

In the following description of embodiments, when a parameter is referred to as being “predetermined,” it may be intended to mean that a value of the parameter is determined in advance of when the parameter is used in a process or an algorithm. The value of the parameter may be set when the process or the algorithm starts or may be set during a period in which the process or the algorithm is being executed.

It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure.

Further, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A logic “high” level and a logic “low” level may be used to describe logic levels of electric signals. A signal having a logic “high” level may be distinguished from a signal having a logic “low” level. For example, when a signal having a first voltage correspond to a signal having a logic “high” level, a signal having a second voltage correspond to a signal having a logic “low” level. In an embodiment, the logic “high” level may be set as a voltage level which is higher than a voltage level of the logic “low” level. Meanwhile, logic levels of signals may be set to be different or opposite according to the embodiments. For example, a certain signal having a logic “high” level in one embodiment may be set to have a logic “low” level in another embodiment.

The term “logic bit set” may mean a combination of logic levels of bits included in a signal. When the logic level of each of the bits included in the signal is changed, the logic bit set of the signal may be set differently. For example, when the signal includes two bits, when the logic level of each of the two bits included in the signal is “logic low level, logic low level”, the logic bit set of the signal may be set as the first logic bit set, and when the logic level of each of the two bits included in the signal is “a logic low level and a logic high level”, the logic bit set of the signal may be set as the second logic bit set.

Various embodiments of the present disclosure will be described hereinafter in more detail with reference to the accompanying drawings. However, the embodiments described herein are for illustrative purposes only and are not intended to limit the scope of the present disclosure.

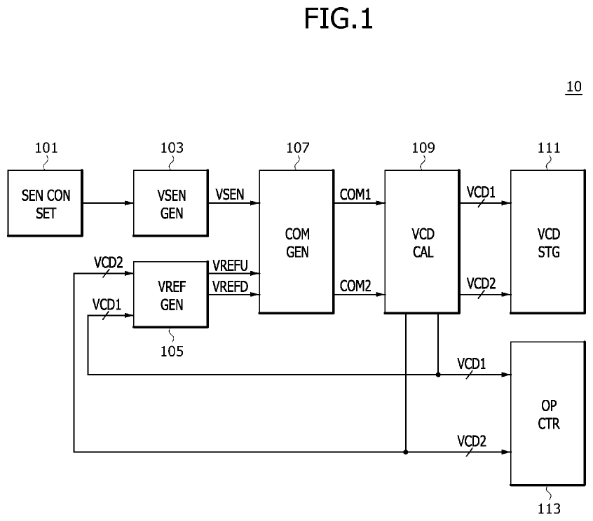

FIG. 1 is a block diagram illustrating a configuration of a sensor circuit 10 according to an embodiment of the present disclosure. As illustrated in FIG. 1, the sensor circuit 10 may include a sensing condition setting circuit (SEN CON SET) 101, a sensing voltage generating circuit (VSEN GEN) 103, a reference voltage generating circuit (VREF GEN) 105, a comparison signal generating circuit (COM GEN) 107, a voltage code calibrating circuit (VCD CAL) 109, a voltage code storage circuit (VCD STG) 111, and an operation control circuit (OP CTR) 113.

The sensing condition setting circuit 101 may apply various operation conditions including temperature, light intensity, etc. to the sensing voltage generating circuit 103. The sensing condition setting circuit 101 may be implemented with a chamber or a light emitter, and may apply sensing conditions for internal calibration operations to the sensing voltage generating circuit 103. As an example, the sensing condition setting circuit 101 may set a first sensing condition so that the sensing voltage generating circuit 103 generates a sensing voltage VSEN set to a voltage level corresponding to high temperature. As another example, the sensing condition setting circuit 101 may set a second sensing condition so that the sensing voltage generating circuit 103 generates the sensing voltage VSEN set to a voltage level corresponding to low temperature.

The sensing voltage generating circuit 103 may generate the sensing voltage VSEN set to a voltage level corresponding to the sensing condition that is set by the sensing condition setting circuit 101. As an example, the sensing voltage generating circuit 103 may generate a sensing voltage VSEN having a set voltage level corresponding to the first sensing condition of high temperature. As another example, the sensing voltage generating circuit 103 may generate a sensing voltage VSEN having a set voltage level corresponding to a second sensing condition of low temperature.

The reference voltage generating circuit 105 may receive a first voltage code VCD1 and a second voltage code VCD2 from the voltage code calibrating circuit 109. The reference voltage generating circuit 105 may generate an upper limit reference voltage VREFU and a lower limit reference voltage VREFD, based on the first voltage code VCD1 and the second voltage code VCD2. The upper limit reference voltage VREFU may be set to have a voltage level higher than that of the lower limit reference voltage VREFD. The reference voltage generating circuit 105 may generate the upper limit reference voltage VREFU and the lower limit reference voltage VREFD, based on the first voltage code VCD1 that is calibrated under the first sensing condition. As an example, the reference voltage generating circuit 105 may generate an upper limit reference voltage VREFU and a lower limit reference voltage VREFD whose respective voltage levels are increased by the first voltage code VCD1 calibrated under the first sensing condition. As another example, the reference voltage generating circuit 105 may generate an upper limit reference voltage VREFU and a lower limit reference voltage VREFD whose respective voltage levels are decreased by the first voltage code VCD1 calibrated under the first sensing condition. The reference voltage generating circuit 105 may generate the upper limit reference voltage VREFU and the lower limit reference voltage VREFD, based on the second voltage code VCD2 calibrated under the first sensing condition. As an example, the reference voltage generation circuit 105 may generate an upper limit reference voltage VREFU and a lower limit reference voltage VREFD whose respective voltage levels are increased by the second voltage code VCD2 calibrated under the second sensing condition. As another example, the reference voltage generating circuit 105 may generate an upper limit reference voltage VREFU and a lower limit reference voltage VREFD whose respective voltage levels are decreased by the second voltage code VCD2 calibrated under the second sensing condition.

The comparison signal generating circuit 107 may receive the sensing voltage VSEN from the sensing voltage generating circuit 103, and may receive the upper limit reference voltage VREFU and the lower limit reference voltage VREFD from the reference voltage generating circuit 105. The comparison signal generating circuit 107 may compare the sensing voltage VSEN with the upper limit reference voltage VREFU and the lower limit reference voltage VREFD to generate a first comparison signal COM1 and a second comparison signal COM2. As an example, the comparison signal generating circuit 107 may generate a first comparison signal COM1 and a second comparison signal COM2 that are set to have a first logic bit set when the sensing voltage VSEN has a higher voltage level than the upper limit reference voltage VREFU. As another example, the comparison signal generating circuit 107 may generate a first comparison signal COM1 and a second comparison signal COM2 that are set to have a second logic bit set when the sensing voltage VSEN has a lower voltage level than the lower limit reference voltage VREFD. As further another example, the comparison signal generating circuit 107 may generate a first comparison signal COM1 and a second comparison signal COM2 that are set to have a third logic bit set when the sensing voltage VSEN has a voltage level that is equal to or higher than that of the lower limit reference voltage VREFD and equal to or lower than that of the upper limit reference voltage VREFU.

The voltage code calibrating circuit 109 may receive the first comparison signal COM1 and the second comparison signal COM2 from the comparison signal generating circuit 107. The voltage code calibrating circuit 109 may calibrate the first voltage code VCD1 and the second voltage code VCD2, based on the first comparison signal COM1 and the second comparison signal COM2. The voltage code calibrating circuit 109 may calibrate the first voltage code VCD1 and the second voltage code VCD2 to adjust the voltage level of each of the upper limit reference voltage VREFU and the lower limit reference voltage VREFD according to the logic bit sets of the first comparison signal COM1 and the second comparison signal COM2. As an example, the voltage code calibrating circuit 109 may calibrate the first voltage code VCD1 and the second voltage code VCD2 to increase the voltage level of each of the upper limit reference voltage VREFU and the lower limit reference voltage VREFD when the sensing voltage VSEN is set to have a voltage level higher than that of the upper limit reference voltage VREFU and the first comparison signal COM1 and second comparison signal COM2 each set to have the first logic bit set are received. As another example, the voltage code calibrating circuit 109 may calibrate the first voltage code VCD1 and the second voltage code VCD2 to decrease the voltage level of each of the upper limit reference voltage VREFU and the lower limit reference voltage VREFD when the sensing voltage VSEN is set to have a voltage level lower than that of the lower limit reference voltage VREFD and the first comparison signal COM1 and the second comparison signal COM2 each set to have the second logic bit set are received. As further another example, the voltage code calibrating circuit 109 may stop the calibration for the first voltage code VCD1 and the second voltage code VCD2 to maintain the voltage level of each of the upper limit reference voltage VREFU and the lower limit reference voltage VREFD when the sensing voltage VSEN is set to have a voltage level equal to or higher than that of the lower limit reference voltage VREFD and equal to lower than that of the upper limit reference voltage VREFU and the first comparison signal COM1 and the second comparison signal COM2 each set to have the third logic bit set are received. The method of calibrating the first voltage code VCD1 and the second voltage code VCD2 to increase or decrease the voltage levels of the upper limit reference voltage VREFU and the lower limit reference voltage VREFD may be set in various ways according to embodiments. As an example, to increase the voltage levels of the upper limit reference voltage VREFU and the lower limit reference voltage VREFD, the first voltage code VCD1 and the second voltage code VCD2 may be calibrated in such a way that each code value is increased. As another example, to decrease the voltage levels of the upper limit reference voltage VREFU and the lower limit reference voltage VREFD, the first voltage code VCD1 and the second voltage code VCD2 may be calibrated in such a way that each code value is decreased.

The voltage code storage circuit 111 may receive and store the first voltage code VCD1 and the second voltage code VCD2 from the voltage code calibrating circuit 109. The voltage code storage circuit 111 may store the first voltage code VCD1 and the second voltage code VCD2 in separately provided storage circuits (not shown). The voltage code storage circuit 111 may store the first voltage code VCD1 calibrated under the first sensing condition, and may store the second voltage code VCD2 calibrated under the second sensing condition. The voltage code storage circuit 111 may sequentially store the first voltage code VCD1 and the second voltage code VCD2, but this is only an embodiment, and other embodiments are not so limited.

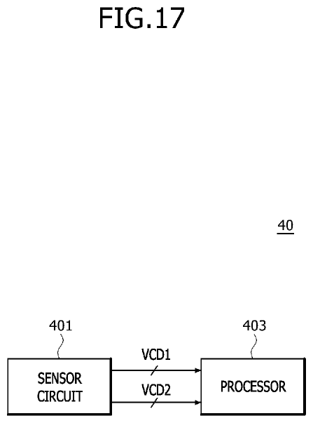

The operation control circuit 113 may receive the first voltage code VCD1 and the second voltage code VCD2 from the voltage code calibrating circuit 109. The operation control circuit 113 may adjust the speed and activation status of an internal operation, and the like, based on the first voltage code VCD1 and the second voltage code VCD2. In this embodiment, the sensor circuit 10 may be implemented to include the operation control circuit 113 and to adjust the speed and activation state of the internal operation, and the like, but may be implemented as a processor (403 in FIG. 17) that receives the first voltage code VCD1 and the second voltage code VCD2 from the sensor circuit 10 according to embodiments.

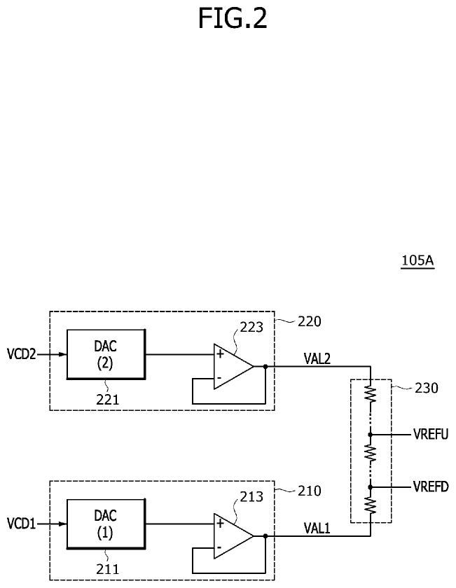

FIG. 2 is a circuit diagram of a reference voltage generating circuit 105A according to an example of the reference voltage generating circuit 105 illustrated in FIG. 1. As illustrated in FIG. 2, the reference voltage generating circuit 105A may include a first analog signal generating circuit 210, a second analog signal generating circuit 220, and a reference voltage output circuit 230.

The first analog signal generating circuit 210 may be implemented with a first digital analog converter (DAC(1)) 211 and a first voltage follower 213. The first digital analog converter 211 may covert the first voltage code VCD1, which is a digital signal, into an analog signal and output the analog signal. The first voltage follower 213 may output the analog signal that is output from the first digital analog converter 211 as a first analog signal VAL1. The first analog signal generating circuit 210 may convert the first voltage code VCD1, which is a digital signal, into an analog signal and output the first analog signal VAL1.

The second analog signal generating circuit 210 may be implemented with a second digital analog converter (DAC(2)) 221 and a second voltage follower 223. The second digital analog converter 221 may covert the second voltage code VCD2, which is a digital signal, into an analog signal and output the analog signal. The second voltage follower 223 may output the analog signal that is output from the second digital analog converter 221 as a second analog signal VAL2. The second analog signal generating circuit 220 may convert the second voltage code VCD2, which is a digital signal, into an analog signal and output the second analog signal VAL2.

The reference voltage output circuit 230 may receive the first analog signal VAL1 from the first analog signal generating circuit 210, and may receive the second analog signal VAL2 from the second analog signal generating circuit 220. The reference voltage output circuit 230 may generate the upper limit reference voltage VREFU and the lower limit reference voltage VREFD, based on the first analog signal VAL1 and the second analog signal VAL2. The reference voltage output circuit 230 may be implemented by including a plurality of resistance elements connected in series between the first analog signal VAL1 and the second analog signal VAL2. The reference voltage output circuit 230 may generate the upper limit reference voltage VREFU and the lower limit reference voltage VREFD that are voltage-divided between the first analog signal VAL1 and the second analog signal VAL2. The reference voltage output circuit 230 may generate the upper limit reference voltage VREFU and the lower limit reference voltage VREFD whose voltage levels increase when the voltage levels of the first analog signal VAL1 and second analog signal VAL2 increase. Meanwhile, the reference voltage output circuit 230 may generate the upper limit reference voltage VREFU and the lower limit reference voltage VREFD whose voltage levels decrease when the voltage levels of the first analog signal VAL1 and the second analog signal VAL2 decrease.

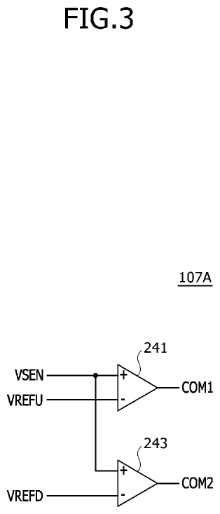

FIG. 3 is a circuit diagram of a comparison signal generating circuit 107A according to an example of the comparison signal generating circuit 107 illustrated in FIG. 1. As illustrated in FIG. 3, the comparison signal generating circuit 107A may include a first comparison signal generating circuit 241 and a second comparison signal generating circuit 243.

The first comparison signal generating circuit 241 may compare the sensing voltage VSEN and the upper limit reference voltage VREFU to generate the first comparison signal COM1. As an example, the first comparison signal generating circuit 241 may generate the first comparison signal COM1 of a logic “high” level when the voltage level of the sensing voltage VSEN is higher than a voltage level of the upper limit reference voltage VREFU. As another example, the first comparison signal generating circuit 241 may generate the first comparison signal COM1 of a logic “low” level when the voltage level of the sensing voltage VSEN is equal to or lower than the voltage level of the upper limit reference voltage VREFU.

The second comparison signal generating circuit 243 may compare the sensing voltage VSEN and the lower limit reference voltage VREFUD to generate the second comparison signal COM2. As an example, the second comparison signal generating circuit 243 may generate the second comparison signal COM2 of a logic “high” level when the voltage level of the sensing voltage VSEN is equal to or higher than the voltage level of the lower limit reference voltage VREFD. As another example, the second comparison signal generating circuit 243 may generate the second comparison signal COM2 of a logic “low” level when the voltage level of the sensing voltage VSEN is lower than the voltage level of the lower limit reference voltage VREFD.

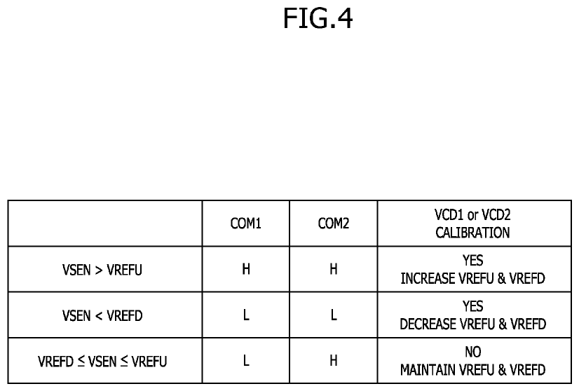

FIGS. 4 to 7 are diagrams illustrating an internal calibration operation performed for each voltage level of the sensing voltage VSEN generated by the sensor circuit 1 illustrated in FIG. 1.

As illustrated in FIG. 4, when the sensing voltage VSEN has a voltage level higher than that of the upper limit reference voltage VREFU, a first comparison signal COM1 and a second comparison signal COM2 set to have a first logic bit set may be generated. The first comparison signal COM1 and the second comparison signal COM2 set to have the first logic bit set may mean a case in which each of the first comparison signal COM1 and the second comparison signal COM2 is set to have a logic “high” level. The first voltage code VCD1 or the second voltage code VCD2 may be calibrated to increase the voltage level of each of the upper limit reference voltage VREFU and the lower limit reference voltage VREFD by the first comparison signal COM1 and the second comparison signal COM2 set to have the first logic bit set.

As illustrated in FIG. 4, when the sensing voltage VSEN has a voltage level lower than that of the lower limit reference voltage VREFD, a first comparison signal COM1 and a second comparison signal COM2 set to have a second logic bit set may be generated. The first comparison signal COM1 and the second comparison signal COM2 set to have the second logic bit set may mean a case in which each of the first comparison signal COM1 and the second comparison signal COM2 is set to have a logic “low” level. The first voltage code VCD1 or the second voltage code VCD2 may be calibrated to decrease the voltage level of each of the upper limit reference voltage VREFU and the lower limit reference voltage VREFD by the first comparison signal COM1 and the second comparison signal COM2 set to have the second logic bit set.

As illustrated in FIG. 4, when the sensing voltage VSEN has a voltage level equal to or higher than that of the lower limit reference voltage VREFD and equal to lower than that of the upper limit reference voltage VREFU, a first comparison signal COM1 and a second comparison signal COM2 set to have a third logic bit set may be generated. The first comparison signal COM1 and the second comparison signal COM2 set to have the third logic bit set may mean a case in which the first comparison signal COM1 is set to have a logic “low” level and the second comparison signal COM2 is set to have a logic “high” level. The first voltage code VCD1 or the second voltage code VCD2 may be calibrated to maintain the voltage level of each of the upper limit reference voltage VREFU and the lower limit reference voltage VREFD by the first comparison signal COM1 and the second comparison signal COM2 set to have the third logic bit set.

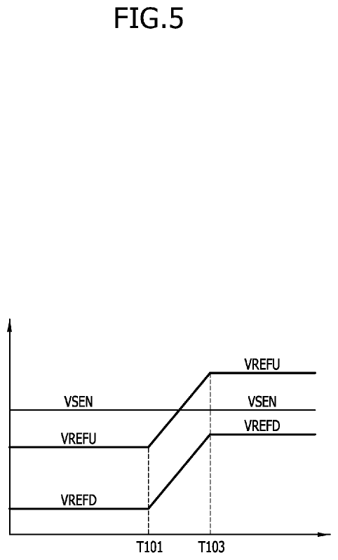

Referring to FIG. 5, an internal calibration operation performed when the sensing voltage VSEN has a voltage level higher than that of the upper limit reference voltage VREFU may be confirmed in more detail. As illustrated in FIG. 5, in a state in which the sensing voltage VSEN has a voltage level higher than that of the upper limit reference voltage VREFU before a point in time T101, the internal calibration operation may be performed during an interval from the point in time T101 to a point in time T103, so that the voltage level of each of the upper limit reference voltage VREFU and the lower limit reference voltage VREFD may be increased. As a result of the internal calibration operation, the sensing voltage VSEN may have a voltage level that is equal to or higher than that of the lower limit reference voltage VREFD and equal to or lower than that of the upper limit reference voltage VREFU after the point in time T103.

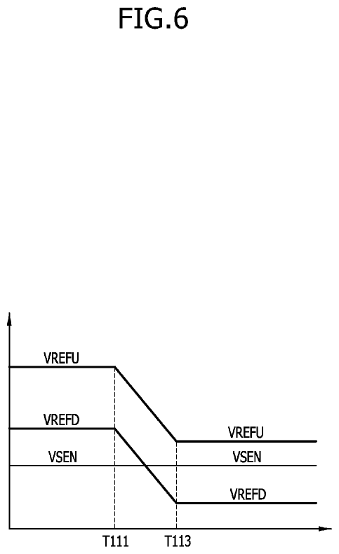

Referring to FIG. 6, an internal calibration operation performed when the sensing voltage VSEN has a voltage level lower than that of the lower limit reference voltage VREFD may be confirmed in more detail. As illustrated in FIG. 6, in a state in which the sensing voltage VSEN has a voltage level lower than that of the lower limit reference voltage VREFD before a point in time T111, the internal calibration operation may be performed during an interval from the point in time T111 to a point in time T113, so that the voltage level of each of the upper limit reference voltage VREFU and the lower limit reference voltage VREFD may be increased. As a result of the internal calibration operation, the sensing voltage VSEN may have a voltage level equal to or higher than that of the lower limit reference voltage VREFD and equal to or lower than that of the upper limit reference voltage VREFU after the point in time T113.

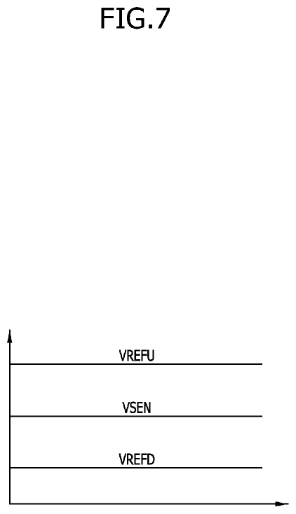

Referring to FIG. 7, it may be seen that an internal calibration operation is not performed when the sensing voltage VSEN has a voltage level that is equal to or higher than that of the lower limit reference voltage VREFD and equal to or lower than that of the upper limit reference voltage VREFU.

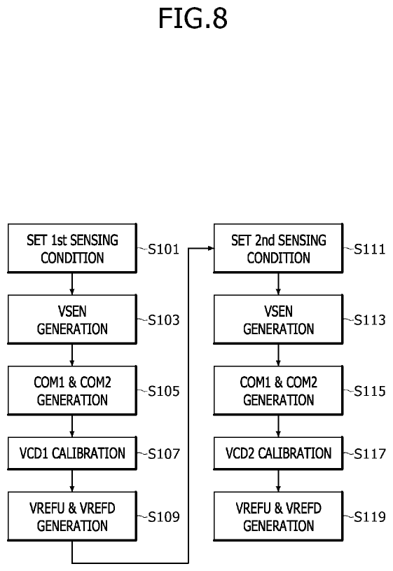

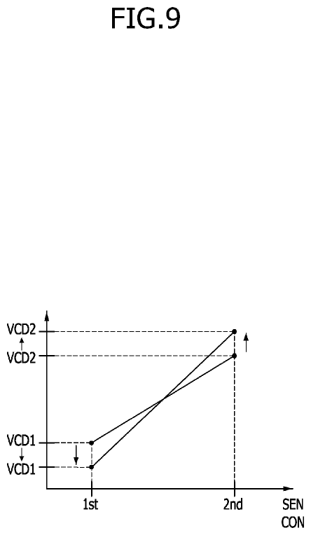

FIGS. 8 and 9 are diagrams illustrating an example of a two-point internal calibration operation performed in the sensor circuit 10 illustrated in FIG. 1. The two-point internal calibration operation may mean that the internal calibration operation is performed under two sensing conditions.

An internal calibration operation performed under a first sensing condition and an internal calibration operation performed under a second sensing condition are described below with reference to FIG. 8.

First, in a state in which the first sensing condition is set (S101), a sensing voltage VSEN corresponding to the first sensing condition may be generated (S103). Next, a first comparison signal COM1 and a second comparison signal COM2 may be generated (S105) according to a voltage level of the sensing voltage VSEN, and a first voltage code VCD1 may be calibrated according to the logic bit set of the first comparison signal COM1 and the second comparison signal COM2 (S107). Next, an upper limit reference voltage VREFU and a lower limit reference voltage VREFD whose voltage levels are adjusted by the calibrated first voltage code VCD1 may be generated (S109). Next, in a state in which the second sensing condition is set (S111), a sensing voltage VSEN corresponding to the second sensing condition may be generated (S113). Next, a first comparison signal COM1 and a second comparison signal COM2 may be generated according to the voltage level of the sensing voltage VSEN (S115), and the second voltage code VCD2 may be calibrated according to the logic bit set of the first comparison signal COM1 and the second comparison signal COM2 (S117). Finally, an upper limit reference voltage VREFU and a lower limit reference voltage VREFD whose voltage levels are adjusted by the calibrated second voltage code VCD2 may be generated (S119).

Referring to FIG. 9, an operation of calibrating the first voltage code VCD1 under the first sensing condition and an operation of calibrating the second voltage code VCD2 under the second sensing condition will be described in detail.

First, when the sensing voltage VSEN generated under the first sensing condition 1st SEN CON has a voltage level lower than that of the lower limit reference voltage VREFD, a code value of the first voltage code VCD1 may be decreased to decrease the voltage levels of the upper limit reference voltage VREFU and the lower limit reference voltage VREFD.

Next, when the sensing voltage VSEN generated under the second sensing condition 2nd SEN CON has a higher voltage level greater than the upper limit reference voltage VREFU, a code value of the second voltage code VCD2 may be increased to increase the voltage levels of the upper limit reference voltage VREFU and the lower limit reference voltage VREFD.

As described above, the sensor circuit 10 may perform the internal calibration operation in which the code value of the first voltage code VCD1 is decreased to decrease the voltage levels of the upper limit reference voltage VREFU and the lower limit reference voltage VREFD under the first sensing condition, and may perform the internal calibration operation in which the code value of the second voltage code VCD2 is increased to increase the voltage levels of the upper limit reference voltage VREFU and the lower limit reference voltage VREFD under the second sensing condition. Because the sensor circuit 10 performs the internal calibration operation at two points including the first sensing condition and the second sensing condition, sensing accuracy can be improved. The sensor circuit 10 internally provides the internal calibration operation for calibrating the first voltage code VCD1 and the second voltage code VCD2 in generating the sensing voltage VSEN for each sensing condition and generating the first voltage code VCD1 and the second voltage code VCD2 corresponding to the sensing voltage VSEN, so that there is no need to provide a separate circuit for calibrating the first voltage code VCD1 and the second voltage code VCD2, thereby reducing layout area and current consumption.

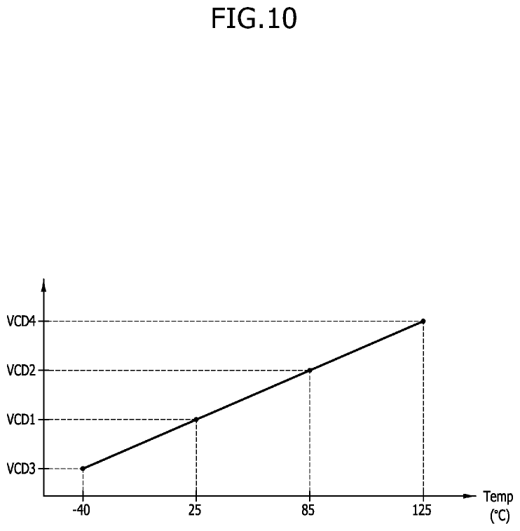

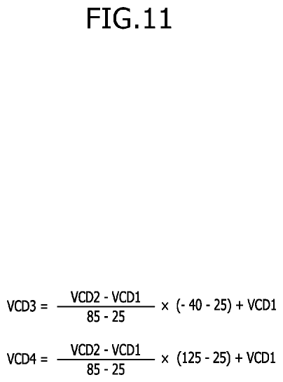

FIGS. 10 and 11 are diagrams illustrating a method of calculating calibrated voltage codes under sensing conditions extended from voltage codes that are calibrated in the internal calibration operations in the sensor circuit 10 illustrated in FIG. 1.

As illustrated in FIG. 10, when a calibrated first voltage code VCD1 is generated under a first sensing condition set to 25° C., and a calibrated second voltage code VCD2 is generated under a second sensing condition set to 85° C., a third voltage code VCD3 under a third sensing condition set to −40° C. and a fourth voltage code VCD4 under a fourth sensing condition set to 125° C., extended from the first voltage code VCD1 and the second voltage code VCD2 may be respectively calculated. This calculation may be performed based on the fact that the third voltage code VCD3 under the third sensing condition set to −40° C. and the fourth voltage code VCD4 under the fourth sensing condition set to 125° C. are located on an extension of a straight line formed between the first voltage code VCD1 under the first sensing condition set to 25° C. and the second voltage code VCD2 under the second sensing condition set to 85° C.

As illustrated in FIG. 11, the voltage level of the third voltage code VCD3 may be calculated by the calculation formula of VCD2−VCD1/85−25×(−40−25)+VCD1 by substituting −40° C. in a linear formula established by the first voltage code VCD1 and the second voltage code VCD2, and the voltage level of the fourth voltage code VCD4 may be calculated by the calculation formula of VCD2−VCD1/85−25×(125−25)+VCD1 by substituting 125° C. into the linear formula.

The sensor circuit 10 according to the present embodiment may additionally extract voltage codes under two sensing conditions through the calculations performed based on the voltage codes calibrated through the internal calibration operation under the two sensing conditions. According to embodiments, the additionally extracted voltage codes may be implemented as three or more. In this way, the sensor circuit 10 may perform the internal calibration operation only under some sensing conditions, and the internal calibration operation under the remaining sensing conditions generates calibrated internal codes by calculation, without the need to perform all internal calibration operations for each sensing condition. Accordingly, consumption of current used for the internal calibration operation may be reduced, and sensing accuracy may be improved by easily adding the number of sensing conditions in which the internal calibration operation is performed.

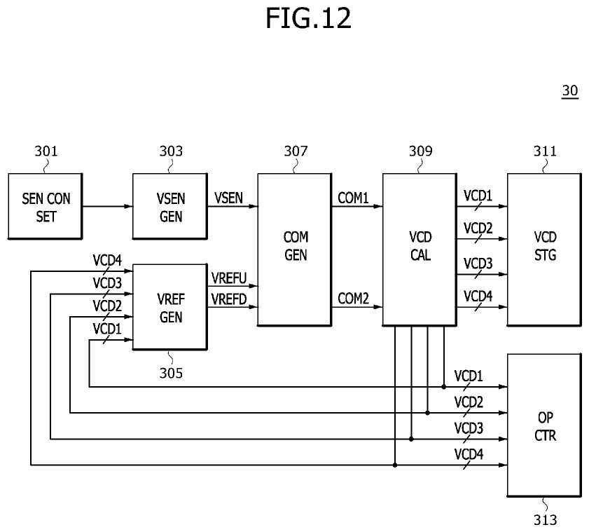

FIG. 12 is a block diagram illustrating a configuration of a sensor circuit 30 according to another embodiment of the present disclosure. As illustrated in FIG. 12, the sensor circuit 30 may include a sensing condition setting circuit (SEN CON SET) 301, a sensing voltage generating circuit (VSEN GEN) 303, a reference voltage generating circuit (VREF GEN) 305, a comparison signal generating circuit (COM GEN) 307, a voltage code calibrating circuit (VCD CAL) 309, a voltage code storage circuit (VCD STG) 311, and an operation control circuit (OP CTR) 313.

The sensing condition setting circuit 301 may apply various operation conditions including temperature, light intensity, etc. to the sensing voltage generating circuit 303. The sensing condition setting circuit 301 may be implemented with a chamber or a light emitter, and may apply sensing conditions for internal calibration operations to the sensing voltage generating circuit 303.

The sensing voltage generating circuit 303 may generate a sensing voltage VSEN corresponding to the sensing conditions set by the sensing condition setting circuit 301. As an example, the sensing voltage generating circuit 303 may generate a sensing voltage VSEN having a set voltage level corresponding to a first sensing condition, may generate a sensing voltage VSEN having a set voltage level corresponding to a second sensing condition, may generate a sensing voltage VSEN having a set voltage level corresponding to a third sensing condition, and may generate a sensing voltage VSEN having a set voltage level corresponding to a fourth sensing condition.

The reference voltage generating circuit 305 may receive a first voltage code VCD1, a second voltage code VCD2, a third voltage code VCD3, and a fourth voltage code VCD4 from the voltage code calibrating circuit 309. The reference voltage generating circuit 305 may generate an upper limit reference voltage VREFU and a lower limit reference voltage VREFD, based on the first voltage code VCD1, the second voltage code VCD2, the third voltage code VCD3, and the fourth voltage code VCD4. The reference voltage generating circuit 305 may generate an upper limit reference voltage VREFU and a lower limit reference voltage VREFD, based on the first voltage code VCD1 calibrated under the first sensing condition. As an example, the reference voltage generating circuit 305 may generate an upper limit reference voltage VREFU and a lower limit reference voltage VREFD whose respective voltage levels are increased by the first voltage code VCD1 calibrated under the first sensing condition.

As another example, the reference voltage generating circuit 305 may generate an upper limit reference voltage VREFU and a lower limit reference voltage VREFD whose respective voltage levels are decreased by the first voltage code VCD1 calibrated under the first sensing condition. The reference voltage generating circuit 305 may generate an upper limit reference voltage VREFU and a lower limit reference voltage VREFD, based on the second voltage code VCD2 calibrated under the second sensing condition. As an example, the reference voltage generating circuit 305 may generate an upper limit reference voltage VREFU and a lower limit reference voltage VREFD whose respective voltage levels are increased by the second voltage code VCD2 calibrated under the second sensing condition. As another example, the reference voltage generating circuit 305 may generate an upper limit reference voltage VREFU and a lower limit decreased by the second voltage code VCD2 calibrated under the second sensing condition. The reference voltage generating circuit 305 may generate an upper limit reference voltage VREFU and a lower limit reference voltage VREFD, based on the third voltage code VCD3 calibrated under the third sensing condition. As an example, the reference voltage generating circuit 305 may generate an upper limit reference voltage VREFU and a lower limit reference voltage VREFD whose respective voltage levels are increased by the third voltage code VCD3 calibrated under the third sensing condition. As another example, the reference voltage generating circuit 305 may generate an upper limit reference voltage VREFU and a lower limit reference voltage VREFD whose respective voltage levels are decreased by the third voltage code VCD3 calibrated under the third sensing condition. The reference voltage generating circuit 305 may generate an upper limit reference voltage VREFU and a lower limit reference voltage VREFD, based on the fourth voltage code VCD4 calibrated under the fourth sensing condition. As an example, the reference voltage generating circuit 305 may generate an upper limit reference voltage VREFU and a lower limit reference voltage VREFD whose respective voltage levels are increased by the fourth voltage code VCD4 calibrated under the fourth sensing condition. As another example, the reference voltage generating circuit 305 may generate an upper limit reference voltage VREFU and a lower limit decreased by the fourth voltage code VCD4 calibrated under the fourth sensing condition.

The comparison signal generating circuit 307 may receive the sensing voltage VSEN from the sensing voltage generating circuit 303, and may receive the upper limit reference voltage VREFU and the lower limit reference voltage VREFD from the reference voltage generating circuit 305. The comparison signal generating circuit 307 may compare the sensing voltage VSEN with the upper limit reference voltage VREFU and the lower limit reference voltage VREFD to generate a first comparison signal COM1 and a second comparison signal COM2.

The voltage code calibrating circuit 309 may receive the first comparison signal COM1 and the second comparison signal COM2 from the comparison signal generating circuit 307. The voltage code calibrating circuit 309 may calibrate the first voltage code VCD1, the second voltage code VCD2, the third voltage code VCD3, and the fourth voltage code VCD4, based on the first comparison signal COM1 and the second comparison signal COM2. The voltage code calibrating circuit 309 may calibrate the first voltage code VCD1, the second voltage code VCD2, the third voltage code VCD3, and the fourth voltage code VCD4, based on logic bit set of the first comparison signal COM1 and the second comparison signal COM2. As an example, the voltage code calibrating circuit 309 may calibrate the first voltage code VCD1, the second voltage code VCD2, the third voltage code VCD3, and the fourth voltage code VCD4 to increase a voltage level of each of the upper limit reference voltage VREFU and the lower limit reference voltage VREFD when the sensing voltage VSEN is set to have a higher voltage level than the upper limit reference voltage VREFU and the first comparison signal COM1 and the second comparison signal COM2 set to have a first logic bit set are received. As another example, the voltage code calibrating circuit 309 may calibrate the first voltage code VCD1, the second voltage code VCD2, the third voltage code VCD3, and the fourth voltage code VCD4 to decrease the voltage level of each of the upper limit reference voltage VREFU and the lower limit reference voltage VREFD when the sensing voltage VSEN is set to have a lower voltage level than the lower limit reference voltage VREFD and the first comparison signal COM1 and the second comparison signal COM2 set to have a second logic bit set are received. As further another example, the voltage code calibrating circuit 109 may stop calibration for the first voltage code VCD1, the second voltage code VCD2, the third voltage code VCD3, and the fourth voltage code VCD4 to maintain the voltage level of each of the upper limit reference voltage VREFU and the lower limit reference voltage VREFD when the sensing voltage VSEN is set to have a voltage level equal to or higher than that of the lower limit reference voltage VREFD and equal to lower than that of the upper limit reference voltage VREFU and the first comparison signal COM1 and the second comparison signal COM2 set to have a third logic bit set are received.

The voltage code storage circuit 311 may receive and store the first voltage code VCD1, the second voltage code VCD2, the third voltage code VCD3, and the fourth voltage code VCD4 from the voltage code calibrating circuit 309. The voltage code storage circuit 311 may store the first voltage code VCD1, the second voltage code VCD2, the third voltage code VCD3, and the fourth voltage code VCD4 in separately provided storage circuits (not shown). The voltage code storage circuit 311 may store the first voltage code VCD1 calibrated under the first sensing condition, may store the second voltage code VCD2 calibrated under the second sensing condition, may store the third voltage code VCD3 calibrated under the third sensing condition, and may store the fourth voltage code VCD4 calibrated under the fourth sensing condition. The voltage code storage circuit 311 may sequentially store the first voltage code VCD1, the second voltage code VCD2, the third voltage code VCD3, and the fourth voltage code VCD4, but this is only an embodiment and the present disclosure is not limited thereto.

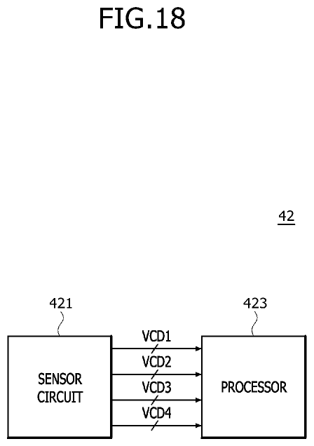

The operation control circuit 313 may receive the first voltage code VCD1, the second voltage code VCD2, the third voltage code VCD3, and the fourth voltage code VCD4 from the voltage code calibrating circuit 309. The operation control circuit 313 may adjust the speed, activation status, and the like of the internal operation, based on the first voltage code VCD1, the second voltage code VCD2, the third voltage code VCD3, and the fourth voltage code VCD4. In this embodiment, the sensor circuit 30 includes the operation control circuit 313 and is implemented to adjust the speed and activation of the internal operations, but may be implemented as a processor (423 in FIG. 18) that receives the first voltage code VCD1, the second voltage code VCD2, the third voltage code VCD3, and the fourth voltage code VCD4 from the sensor circuit 30 according to embodiments.

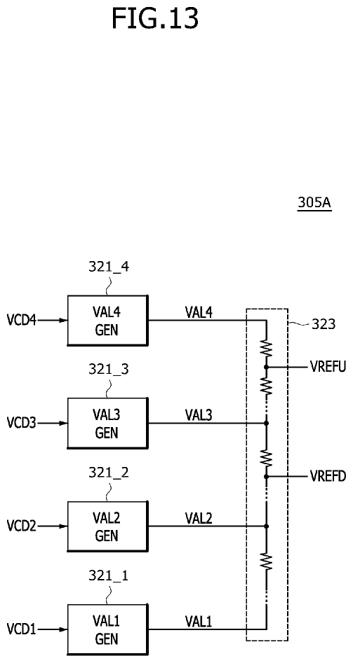

FIG. 13 is a circuit diagram of a reference voltage generating circuit 305A according to an example of the reference voltage generating circuit 305 illustrated in FIG. 12. As illustrated in FIG. 13, the reference voltage generating circuit 305A may include a first analog signal generating circuit 321_1, a second analog signal generating circuit 321_2, a third analog signal generating circuit 321_3, a fourth analog signal generating circuit 321_4, and a reference voltage output circuit 323.

The first analog signal generating circuit 321_1 may convert the first voltage code VCD1, which is a digital signal, into an analog signal and output the analog signal as a first analog signal VAL1. The second analog signal generating circuit 321_2 may convert the second voltage code VCD2, which is a digital signal, into an analog signal and output the analog signal as a second analog signal VAL2. The third analog signal generating circuit 321_3 may convert the third voltage code VCD3, which is a digital signal, into an analog signal and output the analog signal as a third analog signal VAL3. The fourth analog signal generating circuit 321_4 may convert the fourth voltage code VCD4, which is a digital signal, into an analog signal and output the analog signal as a fourth analog signal VAL4.

The reference voltage output circuit 323 may receive the first analog signal VAL1 from the first analog signal generating circuit 321_1, may receive the second analog signal VAL2 from the second analog signal generating circuit 321_2, may receive the third analog signal VAL3 from the third analog signal generating circuit 321_3, and may receive the fourth analog signal VAL4 from the fourth analog signal generating circuit 321_4. The reference voltage output circuit 323 may generate the upper limit reference voltage VREFU and the lower limit reference voltage VREFD, based on the first analog signal VAL1, the second analog signal VAL2, the third analog signal VAL3, and the fourth analog signal VAL4. The reference voltage output circuit 323 may be implemented by including a plurality of resistance elements connected in series to generate the upper limit reference voltage VREFU and the lower limit reference voltage VREFD that are voltage-divided based on the first analog signal VAL1, the second analog signal VAL2, the third analog signal VAL3, and the fourth analog signal VAL4. The reference voltage output circuit 33 may generate the upper limit reference voltage VREFU and the lower limit reference voltage VREFD whose voltage levels increase when the voltage levels of the first analog signal VAL1, the second analog signal VAL2, the third analog signal VAL3, and the fourth analog signal VAL4 increase. Meanwhile, the reference voltage output circuit 323 may generate the upper limit reference voltage VREFU and the lower limit reference voltage VREFD whose voltage levels decrease when the voltage levels of the first analog signal VAL1, the second analog signal VAL2, the third analog signal VAL3, and the fourth analog signal VAL4 decrease.

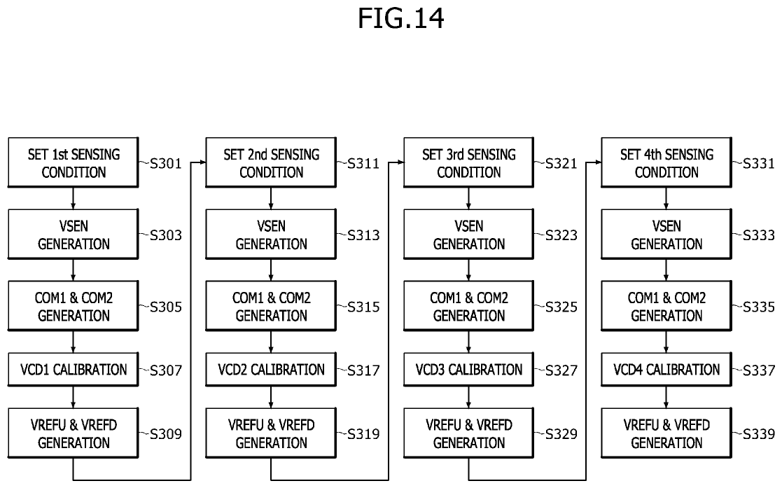

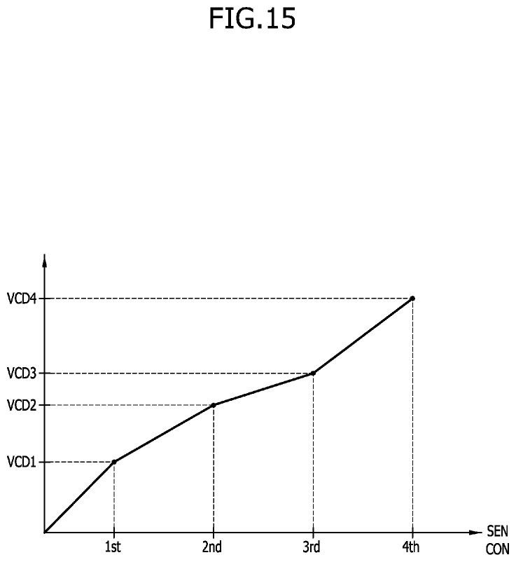

FIGS. 14 and 15 are diagrams illustrating a four-point internal calibration operation performed in the sensor circuit 30 illustrated in FIG. 12. The four-point internal calibration operation may mean that the internal calibration operation is performed under four sensing conditions.

Referring to FIG. 14, an internal calibration operation performed under the first sensing condition, an internal calibration operation performed under the second sensing condition, an internal calibration operation performed under the third sensing condition, and an internal calibration operation performed under the fourth sensing condition will be sequentially described as follows.

First, in a state in which the first sensing condition is set (S301), a sensing voltage VSEN corresponding to the first sensing condition may be generated (S303). Next, a first comparison signal COM1 and a second comparison signal COM2 may be generated according to the voltage level of the sensing voltage VSEN (S305), and the first voltage code VCD1 may be calibrated according to the logic bit set of the first comparison signal COM1 and the second comparison signal COM2 (S307). Next, an upper limit reference voltage VREFU and a lower limit reference voltage VREFD whose voltage levels are adjusted by the calibrated first voltage code VCD1 may be generated (S309). Next, in a state in which the second sensing condition is set (S311), a sensing voltage VSEN corresponding to the second sensing condition may be generated (S313). Next, a first comparison signal COM1 and a second comparison signal COM2 may be generated according to the voltage level of the sensing voltage VSEN (S315), and the second voltage code VCD2 may be calibrated according to the logic bit set of the first comparison signal COM1 and the second comparison signal COM2 (S317). Next, an upper limit reference voltage VREFU and a lower limit reference voltage VREFD whose voltage levels are adjusted by the calibrated second voltage code VCD2 may be generated (S319).

Next, in a state in which the third sensing condition is set (S321), a sensing voltage VSEN corresponding to the third sensing condition may be generated (S323). Next, a first comparison signal COM1 and a second comparison signal COM2 may be generated according to the voltage level of the sensing voltage VSEN (S325), and the third voltage code VCD3 may be calibrated according to the logic bit set of the first comparison signal COM1 and the second comparison signal COM2 (S327). Next, an upper limit reference voltage VREFU and a lower limit reference voltage VREFD whose voltage levels are adjusted by the calibrated third voltage code VCD3 may be generated (S329).

Next, in a state in which the fourth sensing condition is set (S331), a sensing voltage VSEN corresponding to the fourth sensing condition may be generated (S333). Next, a first comparison signal COM1 and a second comparison signal COM2 may be generated according to the voltage level of the sensing voltage VSEN (S335), and the fourth voltage code VCD4 may be calibrated according to the logic bit set of the first comparison signal COM1 and the second comparison signal COM2 (S337). Next, an upper limit reference voltage VREFU and a lower limit reference voltage VREFD whose voltage levels are adjusted by the calibrated fourth voltage code VCD4 may be generated (S339).

Referring to FIG. 15, it is possible to identify a waveform composed of the first voltage code VCD1 under the first sensing condition, the second voltage code VCD2 under the second sensing condition, the third voltage code VCD3 under the third sensing condition, and the fourth voltage code VCD4 under the fourth sensing condition which are calibrated by the four-point internal calibration operation. It can be seen that the waveform composed of the first voltage code VCD1, the second voltage code VCD2, the third voltage code VCD3, and the fourth voltage code VCD4 calibrated by the four-point internal calibration operation is formed in a curved shape reflecting nonlinearity as compared to the waveform composed of the first voltage code VCD1 and the second voltage code VCD2 calibrated by the two-point internal calibration operation, illustrated in FIG. 9. In other words, as the number of sensing conditions in which the internal calibration operation is performed increases, the voltage codes may be calibrated by reflecting the nonlinearity for each sensing condition.

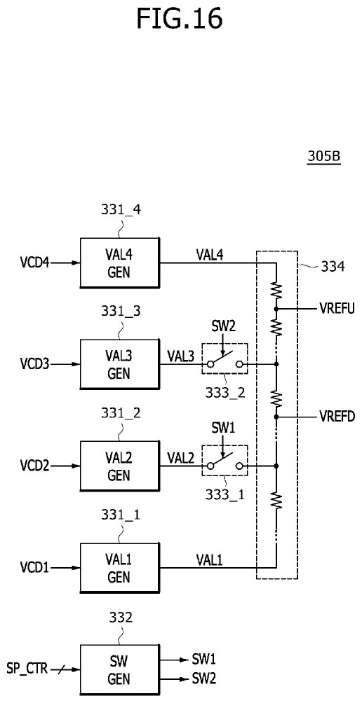

FIG. 16 is a circuit diagram of a reference voltage generating circuit 305B according to an example of the reference voltage generating circuit 305 illustrated in FIG. 12. As illustrated in FIG. 16, the reference voltage generating circuit 305B may include a first analog signal generating circuit 331_1, a second analog signal generating circuit 331_2, a third analog signal generating circuit 331_3, a fourth analog signal generating circuit 331_4, a switching signal generating circuit 332, a first switch 333_1, a second switch 333_2, and a reference voltage output circuit 334.

The first analog signal generating circuit 331_1 may convert the first voltage code VCD1, which is a digital signal, into an analog signal and output the analog signal as a first analog signal VAL1. The second analog signal generating circuit 331_2 may convert the second voltage code VCD2, which is a digital signal, into an analog signal and output the analog signal as a second analog signal VAL2. The third analog signal generating circuit 331_3 may convert the third voltage code VCD3, which is a digital signal, into an analog signal and output the analog signal as a third analog signal VAL3. The fourth analog signal generating circuit 331_4 may convert the fourth voltage code VCD4, which is a digital signal, into an analog signal and output the analog signal as a fourth analog signal VAL4.

The switching signal generating circuit 332 may generate a first switching signal SW1 and a second switching signal SW2, based on a sensing condition control signal SP_CTR. The sensing condition control signal SP_CTR may include bits for which a logic bit set is set according to the number of the sensing conditions for which the internal calibration operation is performed. The sensing condition control signal SP_CTR may be stored in a fuse set (not illustrated) according to whether fuses are cut, or may be stored in a mode register (not illustrated) according to a mode register set operation. As an example, the switching signal generating circuit 332 may generate the first switching signal SW1 and the second switching signal SW2 that are both deactivated when the two-point internal sensing operation is performed. As another example, the switching signal generating circuit 332 may generate the first switching signal SW1 and the second switching signal SW2 that are both activated when the four-point internal sensing operation is performed.

The first switch 333_1 may receive the first switching signal SW1 from the switching signal generating circuit 332 to be turned on. The second switch 333_2 may receive the second switching signal SW2 from the switching signal generating circuit 332 to be turned on. Both the first switch 333_1 and the second switch 333_2 may be turned off according to the first switching signal SW1 and the second switching signal SW2 that are both deactivated when the two-point internal sensing operation is performed. Both the first switch 333_1 and the second switch 333_2 may be turned on according to the first switching signal SW1 and the second switching signal SW2 that are both activated when the four-point internal sensing operation is performed.

The reference voltage output circuit 334 may receive the first analog signal VAL1 from the first analog signal generating circuit 331_1, may receive the second analog signal VAL2 from the second analog signal generating circuit 331_2 when the first switch 333_1 is turned on, may receive the third analog signal VAL3 from the third analog signal generating circuit 331_3 when the second switch 333_2 is turned on, and may receive the fourth analog signal VAL4 from the fourth analog signal generating circuit 331_4. The reference voltage output circuit 334 may generate an upper limit reference voltage VREFU and a lower limit reference voltage VREFD, based on the first analog signal VAL1, the second analog signal VAL2, the third analog signal VAL3, and the fourth analog signal VAL4. The reference voltage output circuit 334 may be implemented by including a plurality of resistance elements connected in series to generate the upper limit reference voltage VREFU and the lower limit reference voltage VREFD that are voltage-divided based on the first analog signal VAL1, the second analog signal VAL2, the third analog signal VAL3, and the fourth analog signal VAL4. The reference voltage output circuit 334 may generate the upper limit reference voltage VREFU and the lower limit reference voltage VREFD whose voltage levels increase when the voltage levels of the first analog signal VAL1, the second analog signal VAL2, the third analog signal VAL3, and the fourth analog signal VAL4 increase. Meanwhile, the reference voltage output circuit 334 may generate the upper limit reference voltage VREFU and the lower limit reference voltage VREFD whose voltage levels decrease when the voltage levels of the first analog signal VAL1 and the second analog signal VAL2, the third analog signal VAL3, and the fourth analog signal VAL4 decrease.

FIG. 17 is a block diagram illustrating a configuration of an electronic device 40 according to an embodiment of the present disclosure. As illustrated in FIG. 17, the electronic device 40 may include a sensor circuit 401 and a processor 403. The sensor circuit 401 may be implemented to perform a two-point internal calibration operation. The sensor circuit 401 may be implemented as the sensor circuit 10 illustrated in FIG. 1 above. The processor 403 may adjust the speed, activation status, and the line of the internal operation, based on a first voltage code VCD1 and a second voltage code VCD2.

FIG. 18 is a block diagram illustrating a configuration of an electronic device 42 according to another embodiment of the present disclosure. As illustrated in FIG. 18, the electronic device 42 may include a sensor circuit 421 and a processor 423. The sensor circuit 421 may be implemented to perform a four-point internal calibration operation. The sensor circuit 421 may be implemented as the sensor circuit 30 illustrated in FIG. 12 above. The processor 423 may adjust the speed, activation status, and the like of the internal operation, based on a first voltage code VCD1, a second voltage code VCD2, a third voltage code VCD3, and a fourth voltage code VCD4.

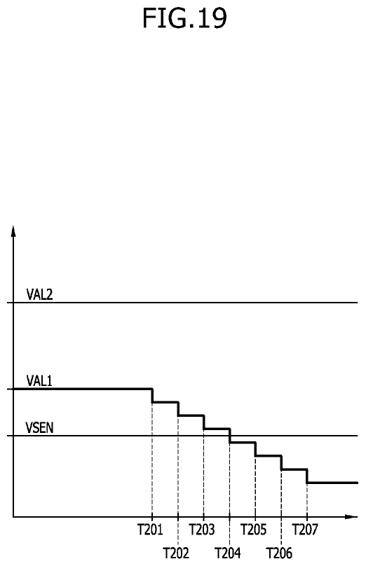

FIG. 19 is a graph illustrating operations in which analog signals are sequentially calibrated for each voltage level of a sensing voltage according to a plurality of internal calibration operations. As illustrated in FIG. 19, first to seventh internal calibration operations may be sequentially performed during an interval from a point in time T201 to a point in time T207. The internal calibration operations performed during the interval from the point in time T201 to the point in time T207 may be performed under one sensing condition or under different sensing conditions, according to different embodiments. Because a voltage level of a first analog signal VAL1 is sequentially decreased according to the internal calibration operations, the voltage level of the sensing voltage VSEN may be located between the respective voltage levels of the first analog signal VAL1 and a second analog signal VAL2 from an interval after a point in time T204. Although only the voltage level of the first analog signal VAL1 is decreased by the internal calibration operations in this embodiment, it has been described only as an example, but is not limited thereto.

Concepts have been disclosed in conjunction with some embodiments as described above. Those skilled in the art will appreciate that various modifications, additions, and/or substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but is defined by the accompanying claims, and all the distinctive features in the equivalent scope should be construed as being included in the concepts.

What is claimed is:

1. A sensor circuit comprising:
a sensing voltage generating circuit configured to generate a sensing voltage set to have a voltage level corresponding to a sensing condition;
a comparison signal generating circuit configured to compare the sensing voltage with at least one reference voltage to generate at least one comparison signal; and
a voltage code calibrating circuit configured to calibrate at least one voltage code for adjusting a voltage level of the at least one reference voltage, based on the at least one comparison signal.

2. The sensor circuit of claim 1, further comprising a sensing condition setting circuit configured to apply the sensing condition to the sensing voltage generating circuit,
wherein the sensing condition includes temperature and light intensity.

3. The sensor circuit of claim 1,
wherein the sensing condition includes a first sensing condition and a second sensing condition, and
wherein the sensing voltage generating circuit is configured to generate the sensing voltage set to a first voltage level corresponding to the first sensing condition, and to generate the sensing voltage set to a second voltage level corresponding to the second sensing condition.

4. The sensor circuit of claim 1,
wherein the at least one reference voltage includes an upper limit reference voltage and a lower limit reference voltage, and
wherein the upper limit reference voltage is set to have a voltage level higher than that of the lower limit reference voltage.

5. The sensor circuit of claim 4,
wherein the at least one comparison signal includes a first comparison signal and a second comparison signal, and
wherein the comparison signal generating circuit is configured to generate the first comparison signal and the second comparison signal set to have a first logic bit set when the sensing voltage has a voltage level greater than that of the upper limit reference voltage.

6. The sensor circuit of claim 5,
wherein the at least one voltage code includes a first voltage code and a second voltage code, and
wherein the voltage code calibrating circuit is configured to calibrate the first voltage code and the second voltage code to increase the voltage level of each of the upper limit reference voltage and the lower limit reference voltage when the first comparison signal and the second comparison signal set to have the first logic bit set are received.

7. The sensor circuit of claim 6, wherein the comparison signal generating circuit is configured to generate the first comparison signal and the second comparison signal set to have a second logic bit set when the sensing voltage has a voltage level lower than that of the lower limit reference voltage.

8. The sensor circuit of claim 7, wherein the voltage code calibrating circuit is configured to calibrate the first voltage code and the second voltage code to decrease the voltage level of each of the upper limit reference voltage and the lower limit reference voltage when the first comparison signal and the second comparison signal set to have the second logic bit set are received.

9. The sensor circuit of claim 8, wherein the comparison signal generating circuit is configured to generate the first comparison signal and the second comparison signal set to have a third logic bit set when the sensing voltage has a voltage level that is equal to or higher than that of the lower limit reference voltage and equal to or lower than that of the upper limit reference voltage.

10. The sensor circuit of claim 9, wherein the voltage code calibrating circuit is configured to stop calibrating the first voltage code and the second voltage code to maintain the voltage level of each of the upper limit reference voltage and the lower limit reference voltage when the first comparison signal and the second comparison signal set to have the third logic bit set are received.

11. The sensor circuit of claim 1,
wherein the reference voltage includes an upper limit reference voltage and a lower limit reference voltage, and
wherein the voltage code includes a first voltage code and a second voltage code,
further comprising a reference voltage generating circuit configured to receive the first voltage code and the second voltage code to adjust a voltage level of each of the upper limit reference voltage and the lower limit reference voltage.

12. The sensor circuit of claim 11, wherein the reference voltage generating circuit includes:
a first analog signal generating circuit configured to convert the first voltage code into a first analog signal and to output the first analog signal;
a second analog signal generating circuit configured to convert the second voltage code into a second analog signal and to output the second analog signal; and
a reference voltage output circuit configured to generate the upper limit reference voltage and the lower limit reference voltage that are voltage-divided based on the first analog signal and the second analog signal.

13. The sensor circuit of claim 11, wherein the reference voltage generating circuit includes:
a first analog signal generating circuit configured to convert the first voltage code into a first analog signal and to output the first analog signal;
a second analog signal generating circuit configured to convert the second voltage code into a second analog signal and to output the second analog signal;
a reference voltage output circuit configured to generate the upper limit reference voltage and the lower limit reference voltage that are voltage-divided based on the first analog signal and the second analog signal; and
a switch configured to transfer the second analog signal output from the second analog signal generating circuit to the reference voltage output circuit, based on a switching signal generated based on a sensing condition control signal.

14. The sensor circuit of claim 13, wherein the sensing condition control signal is stored in a fuse set according to whether fuses are cut or is stored in a mode register according to a mode register set operation.

15. The sensor circuit of claim 1, further comprising a voltage code storage circuit configured to receive and store the voltage code.

16. The sensor circuit of claim 1, further comprising an operation control circuit configured to adjust speed and activation of an internal operation, based on the voltage code.

17. An electronic device comprising:
a sensor circuit configured to compare a sensing voltage set to have a first voltage level under a first sensing condition with at least one reference voltage to generate at least one comparison signal, and configured to calibrate a first voltage code, based on the at least one comparison signal; and
a processor configured to adjust speed and activation of an internal operation, based on the first voltage code.

18. The electronic device of claim 17,
wherein the sensor circuit is configured to compare the sensing voltage set to have a second voltage level under a second sensing condition with the at least one reference voltage to generate the at least one comparison signal, and configured to calibrate a second voltage code, based on the at least one comparison signal, and
wherein the processor is configured to adjust the speed and activation of the internal operation, based on the second voltage code.

19. The electronic device of claim 18,
wherein the at least one reference voltage includes an upper limit reference voltage and a lower limit reference voltage,
wherein the upper limit reference voltage is set to have a voltage level higher than that of the lower limit reference voltage, and
wherein the sensor circuit includes a comparison signal generating circuit configured to generate the first comparison signal and the second comparison signal set to have a first logic bit set when the sensing voltage has a voltage level higher than that of the upper limit reference voltage.

20. The electronic device of claim 19, wherein the sensor circuit further includes a voltage code calibrating circuit configured to calibrate the first voltage code and the second voltage code to increase the voltage level of each of the upper limit reference voltage and the lower limit reference voltage when the first comparison signal and the second comparison signal set to have the first logic bit set are received.

21. The electronic device of claim 20,
wherein the comparison signal generating circuit is configured to generate the first comparison signal and the second comparison signal set to have a second logic bit set when the sensing voltage has a voltage level lower than that of the lower limit reference voltage, and
wherein voltage code calibrating circuit is configured to calibrate the first voltage code and the second voltage code to decrease the voltage level of each of the upper limit reference voltage and the lower limit reference voltage when the first comparison signal and the second comparison signal set to have the second logic bit set are received.

22. The electronic device of claim 21,
wherein the comparison signal generating circuit is configured to generate the first comparison signal and the second comparison signal set to have a third logic bit set when the sensing voltage has a voltage level that is equal to or higher than that of the lower limit reference voltage and equal to or lower than that of the upper limit reference voltage, and
wherein the voltage code calibrating circuit is configured to stop calibration of the first voltage code and the second voltage code to maintain the voltage level of each of the upper limit reference voltage and the lower limit reference voltage when the first comparison signal and the second comparison signal set to have the third logic bit set are received.

23. The electronic device of claim 18,
wherein the at least one reference voltage includes an upper limit reference voltage and a lower limit reference voltage, and
wherein the sensor circuit further includes a reference voltage generating circuit configured to receive the first voltage code and the second voltage code to adjust a voltage level of each of the upper limit reference voltage and the lower limit reference voltage.

24. The electronic device of claim 23, wherein the reference voltage generating circuit includes:
a first analog signal generating circuit configured to convert the first voltage code into a first analog signal and to output the first analog signal;
a second analog signal generating circuit configured to convert the second voltage code into a second analog signal and to output the second analog signal; and
a reference voltage output circuit configured to generate the upper limit reference voltage and the lower limit reference voltage that are voltage-divided based on the first analog signal and the second analog signal.

25. The electronic device of claim 23, wherein the reference voltage generating circuit includes:
a first analog signal generating circuit configured to convert the first voltage code into a first analog signal and to output the first analog signal;
a second analog signal generating circuit configured to convert the second voltage code into a second analog signal and to output the second analog signal;
a reference voltage output circuit configured to generate the upper limit reference voltage and the lower limit reference voltage that are voltage-divided based on the first analog signal and the second analog signal; and
a switch configured to transfer the second analog signal output from the second analog signal generating circuit to the reference voltage output circuit, based on a switching signal generated based on a sensing condition control signal.

26. The electronic device of claim 25, wherein the sensing condition control signal is stored in a fuse set according to whether fuses are cut or is stored in a mode register according to a mode register set operation.

27. The electronic device of claim 18, wherein the sensor circuit further includes a voltage code storage circuit configured to receive and store the first voltage code and the second voltage code.

28. A method of performing an internal calibration operation, the method comprising:
generating a sensing voltage set to have a first voltage level under a first sensing condition;
comparing the sensing voltage with at least one reference voltage to generate at least one comparison signal;
calibrating a first voltage code, based on the at least one comparison signal;
generating the sensing voltage set to have a second voltage level under a second sensing condition;
comparing the sensing voltage with the at least one reference voltage to generate at least one comparison signal; and
calibrating a second voltage code, based on at least one comparison signal.

29. The method of claim 28,
wherein the at least one reference voltage includes an upper limit reference voltage and a lower limit reference voltage,
wherein the upper limit reference voltage is set to have a voltage level higher than that of the lower limit reference voltage, and
wherein the at least one comparison signal includes a first comparison signal and a second comparison signal,
further comprising generating the first comparison signal and the second comparison signal set to have a first logic bit set when the sensing voltage has a voltage level higher than that of the upper limit reference voltage, and calibrating the first voltage code and the second voltage code to increase the voltage level of each of the upper limit reference voltage and the lower limit reference voltage.

30. The method of claim 29, further comprising generating the first comparison signal and the second comparison signal set to have a second logic bit set when the sensing voltage has a voltage level lower than that of the lower limit reference voltage, and calibrating the first voltage code and the second voltage code to decrease the voltage level of each of the upper limit reference voltage and the lower limit reference voltage.

31. The method of claim 29, further comprising generating the first comparison signal and the second comparison signal set to have a third logic bit set when the sensing voltage has a voltage level that is equal to or higher than that of the lower limit reference voltage and equal to or lower than that of the upper limit reference voltage, and stopping calibration of the first voltage code and the second voltage code to maintain the voltage level of each of the upper limit reference voltage and the lower limit reference voltage.

32. The method of claim 28, further comprising adjusting speed and activation of an internal operation, based on the first voltage code and the second voltage code.
